(19) United States
(12) Patent Application Publication
(10) Pub. No.: US 2023/0369083 A1
(43) Pub. Date: Nov. 16, 2023

(54) METHOD FOR OPERATING REACTOR SYSTEM

(71) Applicant: University of Washington, Seattle, WA (US)

(72) Inventors: David Bergsman, Seattle, WA (US); Yuri Choe, Seattle, WA (US); Duncan Reece, Seattle, WA (US)

(21) Appl. No.: 17/740,785

(22) Filed: May 10, 2022

(51) Int. Cl. G05B 19/4155

(52) U.S. Cl. CPC G05B 19/4155; G05B 2219/49021

(57) ABSTRACT

A reactor system includes a first reaction chamber, a second reaction chamber, a resource, one or more processors, and a computer readable medium storing instructions that, when executed by the one or more processors, cause the one or more processors to perform functions. The functions include making a first determination that providing a first reaction chamber access to a resource of a reactor system requires that the first reaction chamber have exclusive access to the resource. The resource includes a reactant source and/or a vacuum pump. The functions also include making a second determination that a second reaction chamber does not require access to the resource. The functions also includes providing the first reaction chamber exclusive access to the resource in response to making the second determination.

### BACKGROUND

One reactor system can be used to deposit different thin film materials on substrates. However, this can involve depositing a first thin film material, purging the reaction chamber, and then depositing the second thin film material, and so on. This can be too time consuming. Different thin film materials can be deposited concurrently using multiple reactor systems that are dedicated to each thin firm material. Each reactor system generally includes a vacuum pump, a reactant vial for each reactant, a computer, and electronic and heating systems. These components all contribute a monetary cost and take up physical space.

### SUMMARY

A first example includes a method comprising: making, via one or more processors, a first determination that providing a first reaction chamber access to a resource of a reactor system requires that the first reaction chamber have exclusive access to the resource, wherein the resource comprises a reactant source and/or a vacuum pump; making, via the one or more processors, a second determination that a second reaction chamber does not require access to the resource; and providing the first reaction chamber exclusive access to the resource in response to making the second determination.

A second example includes a non-transitory computer readable medium storing instructions that, when executed by a computing device, cause the computing device to perform functions comprising: making a first determination that providing a first reaction chamber access to a resource of a reactor system requires that the first reaction chamber have exclusive access to the resource, wherein the resource comprises a reactant source and/or a vacuum pump; making a second determination that a second reaction chamber does not require access to the resource; and providing the first reaction chamber exclusive access to the resource in response to making the second determination.

A third example includes a reactor system comprising: a first reaction chamber; a second reaction chamber; a resource; one or more processors; and a computer readable medium storing instructions that, when executed by the one or more processors, cause the one or more processors to perform functions comprising: making a first determination that providing a first reaction chamber access to a resource of a reactor system requires that the first reaction chamber have exclusive access to the resource, wherein the resource comprises a reactant source and/or a vacuum pump; making a second determination that a second reaction chamber does not require access to the resource; and providing the first reaction chamber exclusive access to the resource in response to making the second determination.

When the term “substantially” or “about” is used herein, it is meant that the recited characteristic, parameter, or value need not be achieved exactly, but that deviations or variations, including, for example, tolerances, measurement error, measurement accuracy limitations, and other factors known to those of skill in the art may occur in amounts that do not preclude the effect the characteristic was intended to provide. In some examples disclosed herein, “substantially” or “about” means within +/−0-5% of the recited value.

These, as well as other aspects, advantages, and alternatives will become apparent to those of ordinary skill in the art by reading the following detailed description, with reference where appropriate to the accompanying drawings. Further, it should be understood that this summary and other descriptions and figures provided herein are intended to illustrate the invention by way of example only and, as such, that numerous variations are possible.

### BRIEF DESCRIPTION OF THE DRAWINGS

FIG. 1 is a schematic diagram of a computing device, according to an example.

FIG. 2 is a schematic diagram of a reactor system, according to an example.

FIG. 3 is a schematic diagram of a reactor system, according to an example.

FIG. 4 is a schematic diagram of a reactor system, according to an example.

FIG. 5 is a schematic diagram of a reactor system, according to an example.

FIG. 6 is a schematic diagram of a reactor system, according to an example.

FIG. 7 is a schematic diagram of a reactor system, according to an example.

FIG. 8 is a block diagram of a method, according to an example.

FIG. 9 is a bar graph depicting thin film growth rate in six different reactor chambers, according to an example.

FIG. 10 is a bar graph depicting thin film growth rate in six different reactor chambers, according to an example.

### DETAILED DESCRIPTION

As discussed above, more efficient techniques and systems for depositing different thin film materials are needed. To this end, this disclosure includes methods for operating a reactor system that may facilitate more efficient deposition of multiple thin film materials.

A method includes making, via one or more processors, a first determination that providing a first reaction chamber access to a resource of a reactor system requires that the first reaction chamber have exclusive access to the resource. The resource comprises a reactant source and/or a vacuum pump. The first reaction chamber might require exclusive access to the vacuum pump to reduce the pressure in the first reaction chamber from atmospheric pressure without interfering with or contaminating other reaction chambers that are at lower pressure. In another situation, the first reaction chamber might require exclusive access to the vacuum pump and the reactant source for a thin film deposition process, so as to maintain a suitable pressure within the first reaction chamber and to prevent contaminating other reaction chambers with the reactants. In yet another situation, the first reaction chamber might require exclusive access to the vacuum pump after an annealing process, to remove stray reactants and other impurities that may be present during and after the annealing process.

The method also includes making, via the one or more processors, a second determination that a second reaction chamber does not require access to the resource. For example, the one or more processors determine that the second reaction chamber is not already using the resource. The method also includes providing the first reaction chamber exclusive access to the resource (e.g., by controlling valves connected to the resource) in response to making the second determination.

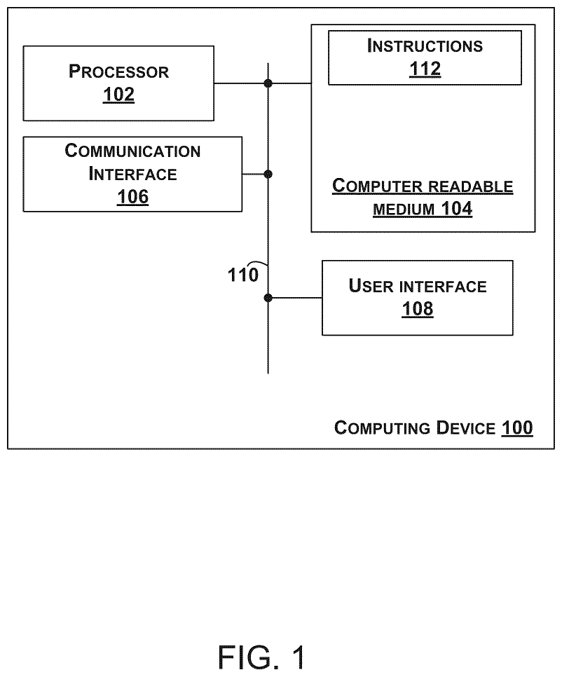

FIG. 1 is a block diagram of a computing device 100. The computing device 100 includes one or more processors 102, a non-transitory computer readable medium 104, a communication interface 106, and a user interface 108. Components of the computing device 100 are linked together by a system bus, network, or other connection mechanism 110.

The one or more processors 102 can be any type of processor(s), such as a microprocessor, a field programmable gate array, a digital signal processor, a multicore processor, etc., coupled to the non-transitory computer readable medium 104.

The non-transitory computer readable medium 104 can be any type of memory, such as volatile memory like random access memory (RAM), dynamic random access memory (DRAM), static random access memory (SRAM), or non-volatile memory like read-only memory (ROM), flash memory, magnetic or optical disks, or compact-disc read-only memory (CD-ROM), among other devices used to store data or programs on a temporary or permanent basis.

Additionally, the non-transitory computer readable medium 104 can store instructions 112. The instructions 112 are executable by the one or more processors 102 to cause the computing device 100 to perform any of the functions or methods described herein.

The communication interface 106 can include hardware to enable communication within the computing device 100 and/or between the computing device 100 and one or more other devices. The hardware can include any type of input and/or output interfaces, a universal serial bus (USB), PCI Express, transmitters, receivers, and antennas, for example. The communication interface 106 can be configured to facilitate communication with one or more other devices, in accordance with one or more wired or wireless communication protocols. For example, the communication interface 106 can be configured to facilitate wireless data communication for the computing device 100 according to one or more wireless communication standards, such as one or more Institute of Electrical and Electronics Engineers (IEEE) 801.11 standards, ZigBee standards, Bluetooth standards, etc. As another example, the communication interface 106 can be configured to facilitate wired data communication with one or more other devices. The communication interface 106 can also include analog-to-digital converters (ADCs) or digital-to-analog converters (DACs) that the computing device 100 can use to control various components of the computing device 100 or external devices.

The user interface 108 can include any type of display component configured to display data. As one example, the user interface 108 can include a touchscreen display. As another example, the user interface 108 can include a flat-panel display, such as a liquid-crystal display (LCD) or a light-emitting diode (LED) display. The user interface 108 can include one or more pieces of hardware used to provide data and control signals to the computing device 100. For instance, the user interface 108 can include a mouse or a pointing device, a keyboard or a keypad, a microphone, a touchpad, or a touchscreen, among other possible types of user input devices. Generally, the user interface 108 can enable an operator to interact with a graphical user interface (GUI) provided by the computing device 100 (e.g., displayed by the user interface 108).

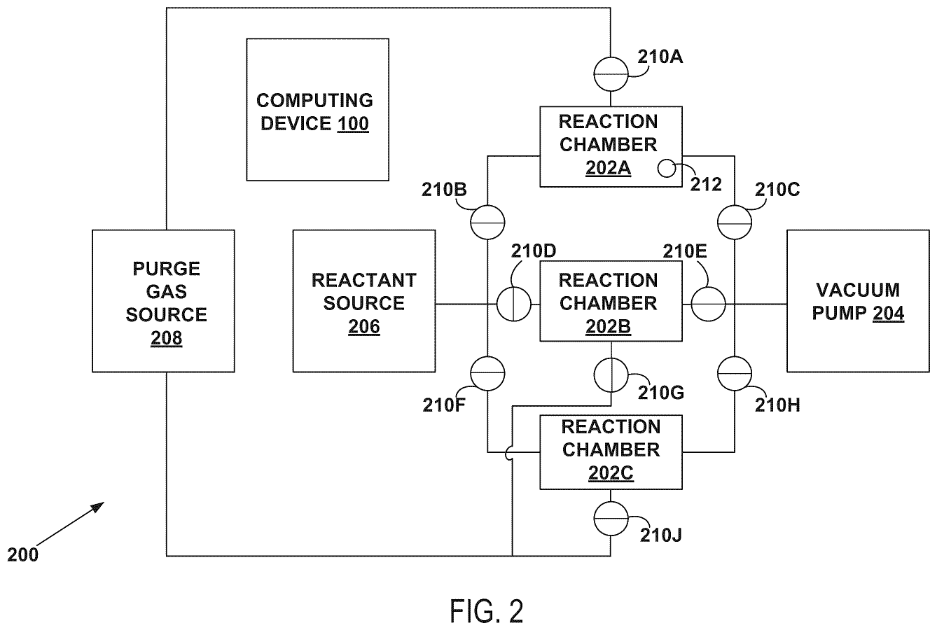

FIG. 2 is a schematic diagram of a reactor system 200. The reactor system 200 includes the computing device 100, a reaction chamber 202A, a reaction chamber 202B, a reaction chamber 202C, a vacuum pump 204, a reactant source 206, a purge gas source 208, a valve 210A, a valve 210B, a valve 210C, a valve 210D, a valve 210E, a valve 210F, a valve 210G, a valve 210H, a valve 210J, and a pressure sensor 212.

The reaction chamber 202A is generally a stainless steel vessel that is configured to maintain an absolute pressure ranging from atmospheric pressure to at least as low as 1 mTorr within the reaction chamber 202A, and typically lower. The reaction chamber 202A also includes a door that allows for inserting and removing a substrate from the reaction chamber 202A and sealing the reaction chamber 202A. The reaction chamber 202A also includes one or more windows for viewing thin film deposition processes within the reaction chamber 202A while the door is closed. The reaction chamber 202A also includes one or more ports configured for fluid tight connection to other components of the reactor system 200. The reaction chamber 202B and the reaction chamber 202C each have any or all of the features of the reaction chamber 202A.

The vacuum pump 204 is typically a mechanical pump connected to ports of the reaction chambers 202A-C and configured for removing gases and vapors from the reaction chambers 202A-C. The vacuum pump 204 is configured to reduce the pressure within the reaction chambers 202A-C to pressures as low as 1 mTorr or lower. In some examples, a turbo pump is used to achieve even lower pressures within the reaction chambers 202A-C.

The reactant source 206 includes one or more containers that each include a single reactant precursor material in the form of a gas or a powder. In some examples, the reactant source 206 includes one or more pressurized metal containers, each containing a gaseous reactant precursor. The reactant precursors can take the form of liquids, gases, or solids. Typically, the evaporated vapor from solids or liquids are used, though liquid forms could be used as well. Examples of reactant precursors include Trimethylaluminum, diethyl zinc, water, ethylene glycol, ethylene diamine, p-phenylene diisocyanate, and ammonia.

As such, the reactant source 206 can include its own internal plumbing and valves that are controlled by the computing device 100 to select a combination of one or more reactive precursors to be provided to the reaction chambers 202A-C.

The purge gas source 208 is a pressurized tank that contains an inert gas such as molecular nitrogen, helium, neon, argon, krypton, or xenon. The inert gas can be used to “purge” or purify the reaction chambers 202A-C after a reaction cycle such that the reaction chambers 202A-C are ready to house a new thin film deposition process without cross contamination.

The valves 210A-J can take the form of pneumatically actuated valves. The computing device 100 opens or closes the valves 210A-J by generating control signals that cause opening or closing of the valves 210A-J.

The valve 210A is configured to open or close a fluid tight connection between the purge gas source 208 and the reaction chamber 202A.

The valve 210B is configured to open or close a fluid tight connection between the reactant source 206 and the reaction chamber 202A.

The valve 210C is configured to open or close a fluid tight connection between the vacuum pump 204 and the reaction chamber 202A.

The valve 210D is configured to open or close a fluid tight connection between the reactant source 206 and the reaction chamber 202B.

The valve 210E is configured to open or close a fluid tight connection between the reaction chamber 202B and the vacuum pump 204.

The valve 210F is configured to open or close a fluid tight connection between the reactant source 206 and the reaction chamber 202C.

The valve 210G is configured to open or close a fluid tight connection between the reaction chamber 202B and the purge gas source 208.

The valve 210H is configured to open or close a fluid tight connection between the vacuum pump 204 and the reaction chamber 202C.

The valve 210J is configured to open or close a fluid tight connection between the reaction chamber 202C and the purge gas source 208.

In the figures, a closed valve is indicated by a line that is perpendicular to the attached plumbing lines, whereas an open valve is indicated by a line that is collinear with the attached plumbing lines.

The pressure sensor 212 is positioned within the reaction chamber 202A and can include any device capable of generating an electrical signal that is indicative of the (e.g., absolute) gas pressure within the reaction chamber 202A.

In various examples, the computing device 100 provides the reaction chambers 202A-C access to a resource of the reactor system 200, that is, the vacuum pump 204 and/or the reactant source 206, based on a state of the reactor system 200 and reaction processes planned for each of the reaction chambers 202A-C. More specifically, the computing device 100 controls the valves 210A-J to selectively provide the reaction chambers 202A-C access to the resource of the reactor system 200.

For instance, the computing device 100 determines that providing the reaction chamber 202A access to the resource of the reactor system 200 requires that the reaction chamber 202A have exclusive access to the resource. Additionally, the computing device 100 determines that that the reaction chamber 202B does not require access to the resource. Next, the computing device 100 provides the reaction chamber 202A exclusive access to the resource in response to determining that that the reaction chamber 202B does not require access to the resource.

FIG. 2 shows that the valves 210A-D, 210F, 210H, and 210J are closed and the valves 210E and 210G are open. Thus, the reaction chamber 202A might be loaded with a substrate and at atmospheric pressure. The reaction chamber 202B might be at approximately 1 Torr and undergoing a “purge” process during which the purge gas source 208 provides purge gas to the reaction chamber 202B and the vacuum pump 204 evacuates the gas or vapor contents of the reaction chamber 202B. The reaction chamber 202C might be at a pressure of approximately 1 Torr and undergoing a “soak” procedure during which the substrate in the reaction chamber 202C is being annealed to facilitate the desired thin film formation after having reactants introduced via the reactant source 206.

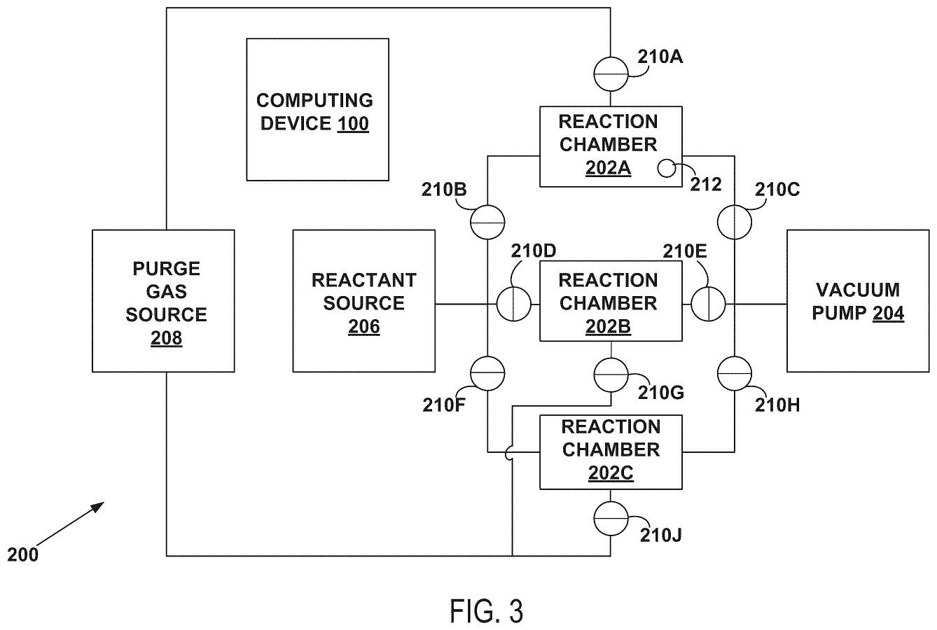

The computing device 100 receives a command for the vacuum pump 204 to evacuate the reaction chamber 202A such that the pressure within the reaction chamber 202A is reduced to about 1 mTorr. The command is received via the user interface 108 or generated by the computing device 100 running an automated program. In response to the command, the computing device 100 determines, based on the pressure (e.g., atmospheric pressure) within the reaction chamber 202A indicated by the pressure sensor 212 or based on information included in the command or accessible to the computing device 100, that using the vacuum pump 204 to evacuate the reaction chamber 202A requires that the reaction chamber 202A have exclusive access to the vacuum pump 204. That is, the computing device 100 determines that the reaction chamber 202A sharing the vacuum pump 204 with the reaction chamber 202B and/or the reaction chamber 202C would cause the higher pressure contents (e.g., air) of the reaction chamber 202A to flow into the lower pressure contents of the reaction chamber 202B and/or the reaction chamber 202C and cause contamination or a disruption in pressure. Thus, the computing device 100 waits until the reaction chamber 202B and the reaction chamber 202C are both isolated from the vacuum pump 204 by the valve 210E and the valve 210H and then opens the valve 210C as shown in FIG. 3, thus giving the reaction chamber 202A exclusive access to the vacuum pump 204.

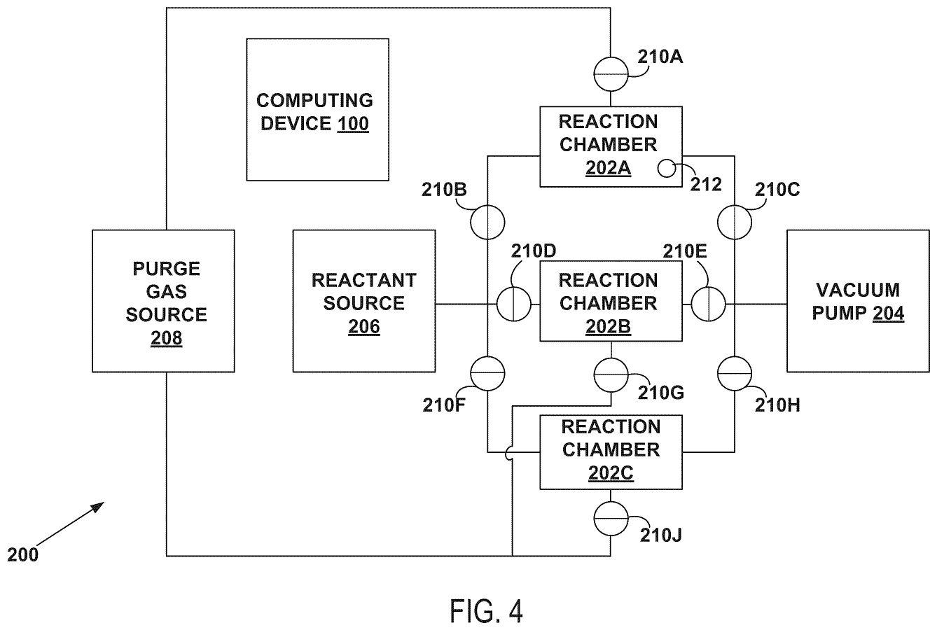

In another example referring to FIG. 2, the computing device 100 receives a command for the vacuum pump 204 to evacuate the reaction chamber 202A while the reactant source 206 provides reactant precursors to the reaction chamber 202A. In response to the command, the computing device 100 determines that using the vacuum pump 204 to evacuate the reaction chamber 202A requires that the reaction chamber 202A have exclusive access to the vacuum pump 204 during the reactant dose process within the reaction chamber 202A, otherwise the reactant precursors could contaminate the reaction chamber 202B and/or the reaction chamber 202C. Thus, the computing device 100 waits until the reaction chamber 202B and the reaction chamber 202C are isolated from both the vacuum pump 204 and the reactant source 206 and then opens the valve 210B and the valve 210C as shown in FIG. 4, thus giving the reaction chamber 202A exclusive access to the vacuum pump 204 and the reactant source 206.

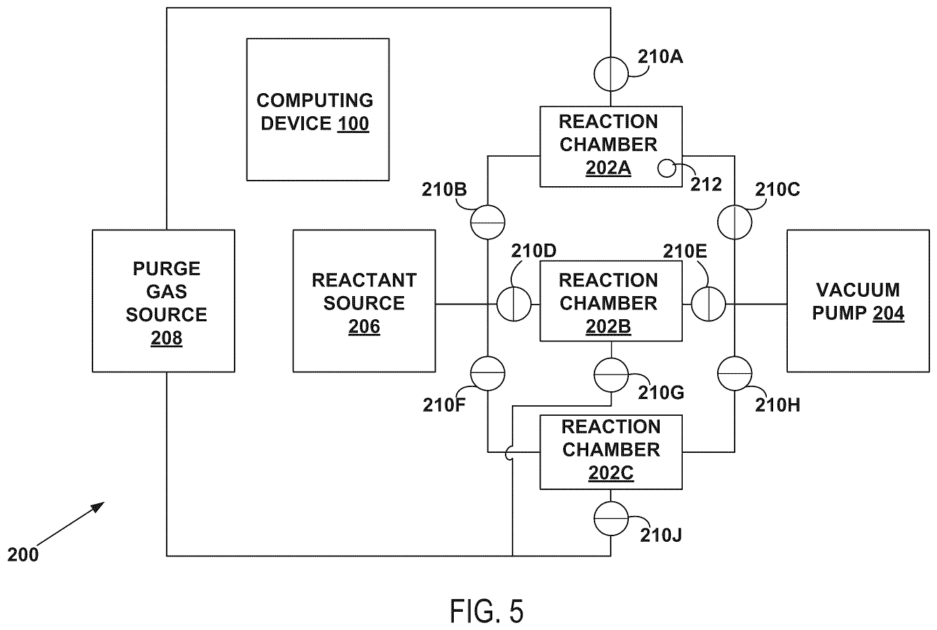

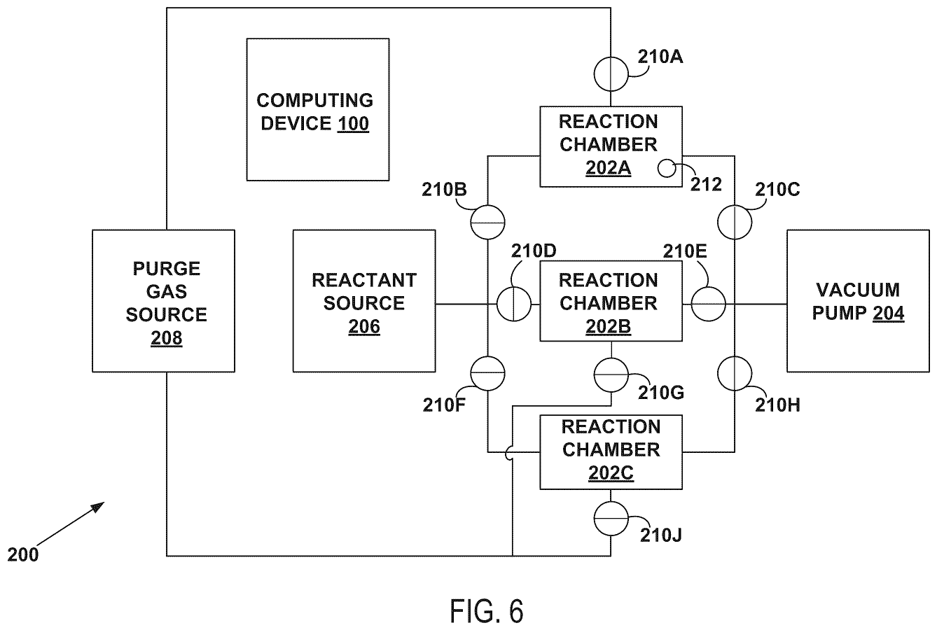

Referring again to FIG. 2, the reaction chamber 202A could be undergoing a “soak” procedure during which the substrate in the reaction chamber 202A is being annealed to facilitate the desired thin film formation after having reactants introduced via the reactant source 206. In a transition to a “purge” step, the computing device 100 receives a command for the vacuum pump 204 to evacuate the reaction chamber 202A while the purge gas source 208 provides purge gas to the reaction chamber 202A. In response to the command, the computing device 100 determines that using the vacuum pump 204 to evacuate the reaction chamber 202A requires that the reaction chamber 202A have exclusive access to the vacuum pump 204 during the initial purge process within the reaction chamber 202A. For example, the computing device 100 determines that the pressure within the reaction chamber 202A indicates that reactants and reaction products could still be within the reaction chamber 202A and, based on that, determines that the reaction chamber 202A requires exclusive access to the vacuum pump 204. Without the reaction chamber 202A having exclusive access to the vacuum pump 204, reactant precursors or reactant products could contaminate the reaction chamber 202B and/or the reaction chamber 202C if the reaction chamber 202B and/or the reaction chamber 202C were concurrently being evacuated by the vacuum pump 204. Thus, the computing device 100 waits until the reaction chamber 202B and the reaction chamber 202C are both isolated from the vacuum pump 204 and then opens the valve 210A and the valve 210C as shown in FIG. 5. After the pressure within the reaction chamber 202A is reduced to about 1 mTorr, it can be assumed that the reaction chamber 202A no longer contains significant levels of contaminants and the reaction chamber 202A can share the vacuum pump 204 with the reaction chamber 202B and/or the reaction chamber 202C as shown in FIG. 6, if the processes within the reaction chamber 202B and/or the reaction chamber 202C are compatible. Alternatively, the computing device 100 can set a timer (e.g., for a few minutes) to allow for the initial purge of the reaction chamber 202A, after which the reaction chamber 202A can be assumed to no longer contain significant levels of contaminants. Upon expiration of the timer, the reaction chamber 202A can share the vacuum pump 204 with the reaction chamber 202B and/or the reaction chamber 202C as shown in FIG. 6.

In some examples, the computing device 100 determines whether the reaction chamber 202A, the reaction chamber 202B, or the reaction chamber 202C require access to the vacuum pump 204 and/or the reactant source 206 based on the current state of the valves 210A-J. For example, the computing device 100 maintains a log of whether each of the valves 210A-J are open or closed. In other examples, the computing device 100 is configured to detect whether each of the valves 210A-J is open or closed.

For instance, the computing device 100 determines that the reaction chamber 202A needs access to the vacuum pump 204 by determining that the valve 210C is open and determines that the reaction chamber 202A does not need access to the vacuum pump 204 by determining that the valve 210C is closed. The computing device 100 determines that the reaction chamber 202A needs access to the reactant source 206 by determining that the valve 210B is open and determines that the reaction chamber 202A does not need access to the reactant source 206 by determining that the valve 210B is closed.

The computing device 100 determines that the reaction chamber 202B needs access to the vacuum pump 204 by determining that the valve 210E is open and determines that the reaction chamber 202B does not need access to the vacuum pump 204 by determining that the valve 210E is closed. The computing device 100 determines that the reaction chamber 202B needs access to the reactant source 206 by determining that the valve 210D is open and determines that the reaction chamber 202B does not need access to the reactant source 206 by determining that the valve 210D is closed.

The computing device 100 determines that the reaction chamber 202C needs access to the vacuum pump 204 by determining that the valve 210H is open and determines that the reaction chamber 202C does not need access to the vacuum pump 204 by determining that the valve 210H is closed. The computing device 100 determines that the reaction chamber 202C needs access to the reactant source 206 by determining that the valve 210F is open and determines that the reaction chamber 202C does not need access to the reactant source 206 by determining that the valve 210F is closed.

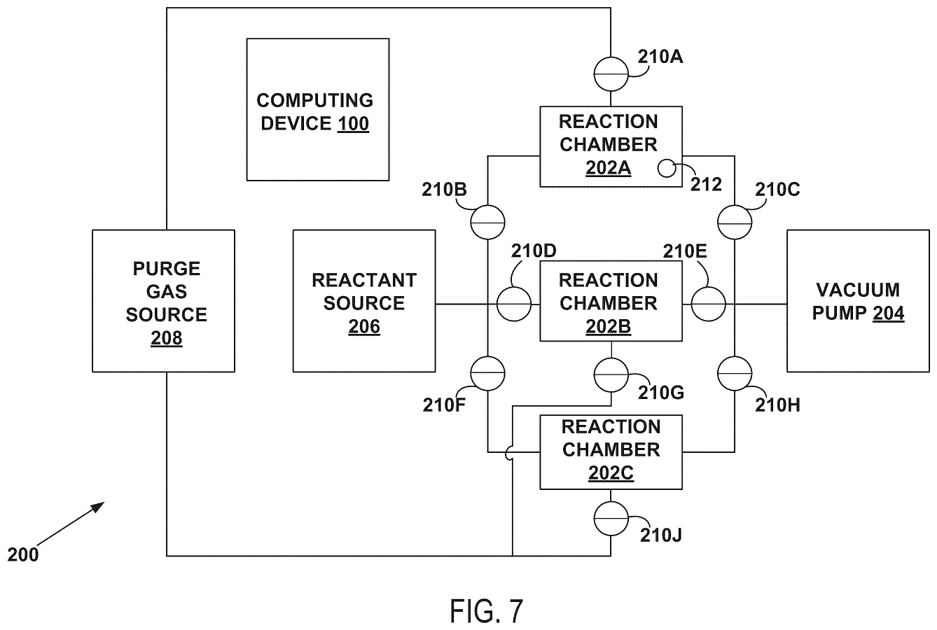

In various examples, the reaction chamber 202B might require exclusive or non-exclusive access to the vacuum pump 204 and/or the reactant source 206, for reasons similar to those described above for the reaction chamber 202A. As such, the computing device 100 determines that the reaction chamber 202B requires exclusive access to the vacuum pump 204 and/or the reactant source 206. Next, the computing device 100 determines whether the reaction chamber 202A or the reaction chamber 202C require access to the vacuum pump 204 and/or the reactant source 206, and provides the reaction chamber 202B exclusive access to the vacuum pump 204 and/or the reactant source 206 upon determining that the reaction chamber 202A and the reaction chamber 202C do not require access to the vacuum pump 204 and/or the reactant source 206, as shown in FIG. 7.

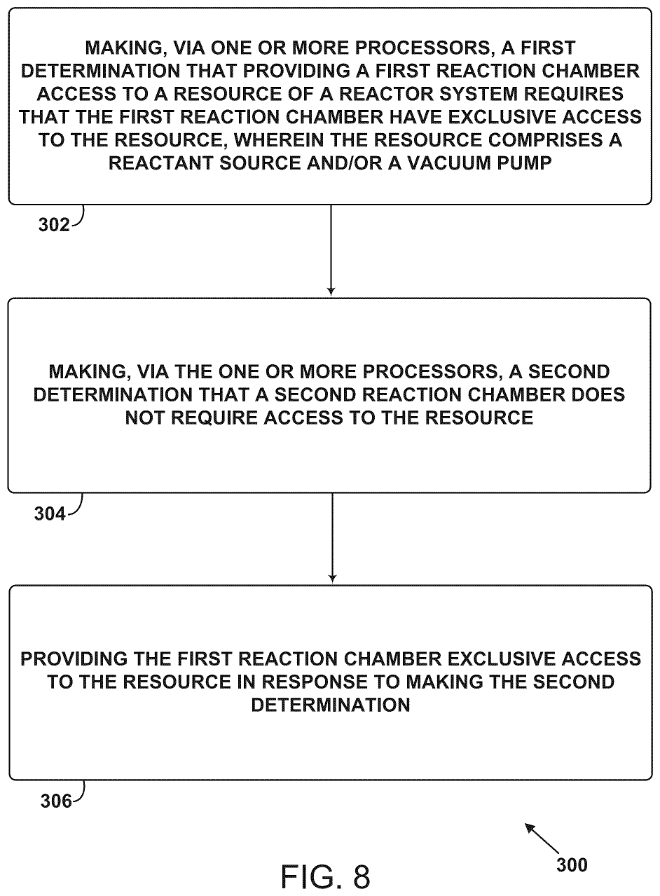

FIG. 8 is a block diagram of a method 300 for the computing device 100 controlling the reactor system 200. As shown in FIG. 8, the method 300 includes one or more operations, functions, or actions as illustrated by blocks 302, 304, and 306. Although the blocks are illustrated in a sequential order, these blocks may also be performed in parallel, and/or in a different order than those described herein. Also, the various blocks may be combined into fewer blocks, divided into additional blocks, and/or removed based upon the desired implementation.

At block 302, the method 300 includes the computing device 100 making, via the one or more processors 102, a first determination that providing the reaction chamber 202A access to a resource of the reactor system 200 requires that the reaction chamber 202A have exclusive access to the resource. The resource comprises the reactant source 206 and/or the vacuum pump 204. This functionality is described above with reference to FIGS. 2-6.

At block 304, the method 300 includes the computing device 100 making, via the one or more processors 102, a second determination that the reaction chamber 202B does not require access to the resource. This functionality is described above with reference to FIGS. 2-6.

At block 306, the method 300 providing the reaction chamber 202A exclusive access to the resource in response to making the second determination. This functionality is described above with reference to FIGS. 2-6.

While various example aspects and example embodiments have been disclosed herein, other aspects and embodiments will be apparent to those skilled in the art. The various example aspects and example embodiments disclosed herein are for purposes of illustration and are not intended to be limiting, with the true scope and spirit being indicated by the following claims.

### ADDITIONAL EXAMPLES

Reactor independence is demonstrated by performing depositions in one chamber and measuring any accidental growth in other chambers using ellipsometry. Initial experimentation suggests that cross-contamination between chambers is usually prevented if (a) each chamber is allowed exclusive pump access to initially purge before sharing the pump with other purging chambers, and (b) pump valves are given sufficient time to close before any chamber initially begins to purge. Together, this work suggest that a single lab-scale reactor can be constructed with higher sample throughput than would be capable with a more typical single-chamber design, without the cost of constructing an equivalent number of independent reactors.

Pneumatic valves separating each chamber from the pumps and dosing lines are controlled by mouse valves, which are themselves controlled by solid state relays attached to a computer. The computer runs a custom-built LabVIEW program that manages all valves.

Reactor Advantages/Trade-offs: Combining several chambers into the same reactor reduces redundancy by sharing common resources such as pumps, computers, table space, and electronics. Sharing these resources also allows several chambers to run the same process with different conditions (a) without added cost from redundant reactant assemblies, and (b) much more quickly than a single chamber exploring each set of conditions consecutively. Access to shared resources is managed with a software scheduler.

Operating Software and Algorithm: During a typical ALD or MLD process, reaction chambers must be able to pump to vacuum, dose reactants (with and without vacuum and purge gas), soak in the reactants, purge with inert gas, and return to atmospheric pressure, all with set periods of time. Most of these tasks require some level of exclusive access to a shared dosing or pumping line. For example, reactant dosing, which can require pumping or purging, generally can't be performed while another chamber is purging without risk of cross-contamination. However, multiple chambers can purge simultaneously, due to the pressure gradient formed by the inert purge gasses.

To address this conflict, the reactor control software uses a “lock” system. A reactor wishing to perform a step requiring exclusive access to the pump or shared lines may request the lock for that line, which prevents any other reactor from claiming the lock. It then releases the lock when finished. If a reactor with the pump lock wishes to access the pump, it closes the valves for all other chambers before continuing, to avoid cross-contamination. Reactors trying to claim an already claimed lock must wait until the lock is released before proceeding, creating a short delay. Because each reactor only tries to claim locks before dosing or purging, this delay only causes longer-than-normal purge times or exposure times respectively (which are usually not a large concern for an ALD-style self-saturating process). Regardless, these delays are often avoided, since purge times are generally longer than doses.

Process Validation and Cross-contamination: To demonstrate that the reaction chambers can operate independently, TMA+water processes were performed in one of the chambers while control samples were placed in the other chambers. Ellipsometry results (FIG. 4) showed that a short delay of 1 second between closing the valves on the other chambers and dosing the reactants into Chamber 1 is required to avoid cross-contamination. We further show (FIG. 4) that deposition can be performed in multiple chambers with nearly identical deposition thicknesses without significant cross-contamination. The high TMA+water growth per cycle is attributed to a lack of process optimization.

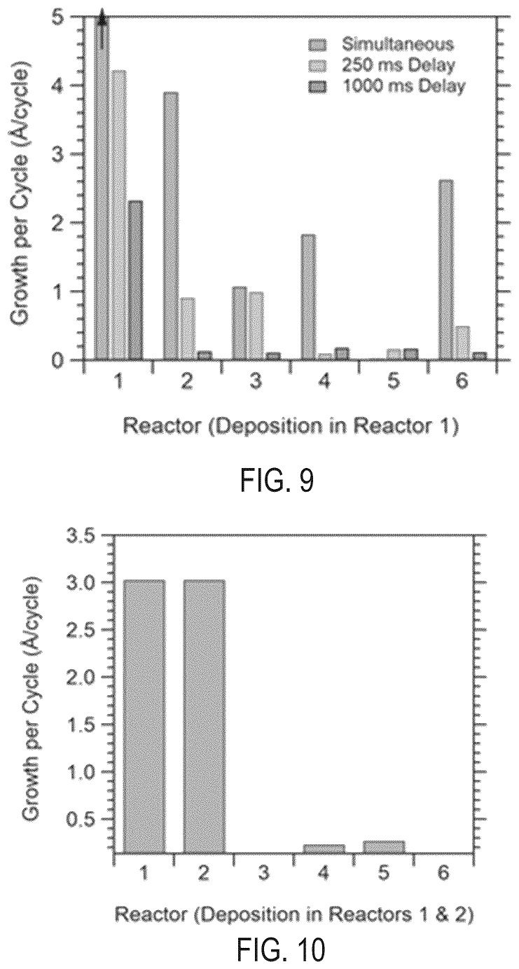

FIG. 9 shows ellipsometry results, that is, a cross-contamination check using 10 cycles of a TMA+Water process. Growth per cycle in each chamber when the process is run in chamber 1 is shown. To reduce cross-contamination, the valves in other chambers are closed before dosing into chamber 1 with a 0 ms, 250 ms, or 1000 ms delay. FIG. 10 shows growth per cycle in each chamber when the process is run in chambers 1 and 2. Growth in the two reactors is identical with minimal cross-contamination. Growth rates are high for TMA+water due to the process not being fully optimized.

What is claimed is:

1. A method comprising:
making, via one or more processors, a first determination that providing a first reaction chamber access to a resource of a reactor system requires that the first reaction chamber have exclusive access to the resource, wherein the resource comprises a reactant source and/or a vacuum pump;
making, via the one or more processors, a second determination that a second reaction chamber does not require access to the resource; and
providing the first reaction chamber exclusive access to the resource in response to making the second determination.

2. The method of claim 1, wherein the resource comprises the vacuum pump, and wherein making the first determination comprises determining, based on a pressure within the first reaction chamber, that using the vacuum pump to evacuate the first reaction chamber requires that the first reaction chamber have exclusive access to the vacuum pump.

3. The method of claim 1, wherein the resource comprises the vacuum pump, and wherein making the first determination comprises determining that using the vacuum pump to evacuate the first reaction chamber requires that the first reaction chamber have exclusive access to the vacuum pump during a reactant dose process within the first reaction chamber.

4. The method of claim 1, wherein the resource comprises the vacuum pump, and wherein making the first determination comprises determining that using the vacuum pump to evacuate the first reaction chamber requires that the first reaction chamber have exclusive access to the vacuum pump based on a presence of reactants within the first reaction chamber.

5. The method of claim 1, wherein the resource comprises the reactant source, and wherein making the first determination comprises determining that using the reactant source to provide reactants to the first reaction chamber requires that the first reaction chamber have exclusive access to the reactant source.

6. The method of claim 1, further comprising:
making a third determination that the second reaction chamber requires access to the resource;
making a fourth determination that the first reaction chamber no longer requires exclusive access to the resource; and
providing the second reaction chamber access to the resource in response to making the fourth determination.

7. The method of claim 1, further comprising making a third determination that the second reaction chamber requires access to the resource prior to making the second determination.

8. The method of claim 7, wherein the resource comprises the vacuum pump, and wherein making the third determination comprises determining that a valve that connects the second reaction chamber to the vacuum pump is open.

9. The method of claim 7, wherein the resource comprises the reactant source, and wherein making the third determination comprises determining that a valve that connects the second reaction chamber to the reactant source is open.

10. The method of claim 1, wherein the resource comprises the vacuum pump, and wherein making the second determination comprises determining that a valve that connects the second reaction chamber to the vacuum pump is closed.

11. The method of claim 1, wherein the resource comprises the reactant source, and wherein making the second determination comprises determining that a valve that connects the second reaction chamber to the reactant source is closed.

12. The method of claim 1, wherein providing the first reaction chamber access to the resource comprises generating a control signal, thereby opening a valve that connects the resource to the first reaction chamber.

13. The method of claim 1, wherein making the second determination comprises determining that one or more third reaction chambers also do not require access to the resource.

14. A non-transitory computer readable medium storing instructions that, when executed by a computing device, cause the computing device to perform functions comprising:
making a first determination that providing a first reaction chamber access to a resource of a reactor system requires that the first reaction chamber have exclusive access to the resource, wherein the resource comprises a reactant source and/or a vacuum pump;
making a second determination that a second reaction chamber does not require access to the resource; and
providing the first reaction chamber exclusive access to the resource in response to making the second determination.

15. The non-transitory computer readable medium of claim 14, wherein making the second determination comprises determining that one or more third reaction chambers also do not require access to the resource.

16. A reactor system comprising:
a first reaction chamber;
a second reaction chamber;
a resource;
one or more processors; and
a computer readable medium storing instructions that, when executed by the one or more processors, cause the one or more processors to perform functions comprising:
making a first determination that providing the first reaction chamber access to the resource requires that the first reaction chamber have exclusive access to the resource, wherein the resource comprises a reactant source and/or a vacuum pump;
making a second determination that the second reaction chamber does not require access to the resource; and
providing the first reaction chamber exclusive access to the resource in response to making the second determination.

17. The reactor system of claim 16, wherein the resource comprises the vacuum pump, and wherein making the first determination comprises determining, based on a pressure within the first reaction chamber, that using the vacuum pump to evacuate the first reaction chamber requires that the first reaction chamber have exclusive access to the vacuum pump.

18. The reactor system of claim 16, wherein the resource comprises the vacuum pump, and wherein making the first determination comprises determining that using the vacuum pump to evacuate the first reaction chamber requires that the first reaction chamber have exclusive access to the vacuum pump during a reactant dose process within the first reaction chamber.

19. The reactor system of claim 16, wherein the resource comprises the vacuum pump, and wherein making the first determination comprises determining that using the vacuum pump to evacuate the first reaction chamber requires that the first reaction chamber have exclusive access to the vacuum pump based on a presence of reactants within the first reaction chamber.

20. The reactor system of claim 16, further comprising one or more third reaction chambers, wherein making the second determination comprises determining that the one or more third reaction chambers also do not require access to the resource.
